(19) United States
(12) Patent Application Publication
(10) Pub. No.: US 2018/0198029 A1
(43) Pub. Date: Jul. 12, 2018

(54) SEMICONDUCTOR LIGHT EMITTING DEVICE INCLUDING REFLECTIVE ELEMENT AND METHOD OF MAKING SAME

(71) Applicant: GLO AB, Lund (SE)

(72) Inventors: Mariana MUNTEANU, Sunnyvale, CA (US); Fariba DANESH, Pleasanton, CA (US)

(21) Appl. No.: 15/863,035

(22) Filed: Jan. 5, 2018

Related U.S. Application Data
(60) Provisional application No. 62/443,953, filed on Jan. 9, 2017.

(51) Int. Cl. H01L 33/40; H01L 33/06; H01L 33/32; H01L 33/24; H01L 33/44; H01L 33/00; H01L 33/12

(52) U.S. Cl. CPC H01L 33/405; H01L 33/06; H01L 33/32; H01L 2933/0016; H01L 33/44; H01L 33/0075; H01L 33/12; H01L 33/24

(57) ABSTRACT

A light emitting device and method of forming the same, the method including etching grooves into semiconductor layers disposed on a substrate to form mesas, forming an insulating layer on the mesas, etching the insulating layer to expose upper surfaces of the mesas, and forming a reflective contact layer on the mesas. The contact layer may include protrusions disposed in the grooves on the etched insulating layer, and facing sidewalls of the mesas.

### FIELD

Aspects of the present disclosure relate to semiconductor light emitting devices, such as light emitting diodes (LED), and in particular to LEDs having reflective elements configured to improve light extraction efficiency.

### BACKGROUND

Semiconductor devices are ubiquitous in modern society and semiconductor manufacturers, for example manufacturers of solid state lighting devices, are constantly seeking to improve the performance of their products. Recently, light emitting devices based on gallium nitride (GaN) have found a wide range of application. In particular, high brightness LEDs based on GaN have been widely used, for example in backlighting of LCDs, traffic signals, full color displays and street lights. GaN LEDs have also recently started to enter the general lighting market.

In order to be more effective in general lighting applications, the performance of GaN LEDs should be further improved. Accordingly, there is a need for GaN LEDs having improved light extraction efficiency.

### SUMMARY

According to various embodiments, a method of forming a light emitting device comprises forming a first semiconductor layer on a substrate; forming an active layer on the first semiconductor layer and configured to emit light; forming a second semiconductor layer on the active layer; etching grooves into the second semiconductor layer and the active layer to form mesas; forming an insulating layer on the mesas; etching the insulating layer to expose upper surfaces of the mesas; and forming a reflective contact layer on the mesas.

According to various embodiments, a light emitting device comprises a first semiconductor layer having a first conductivity type; an active layer disposed on an upper surface of the first semiconductor layer and configured to emit light; a second semiconductor layer disposed on an upper surface of the active layer and having a second conductivity type different from the first conductivity type; an insulating layer covering sidewalls of the active layer and the second semiconductor layer; and a reflective contact layer disposed on an upper surface of the second semiconductor layer and comprising protrusions disposed on the insulating layer facing the sidewalls of the active layer and the second semiconductor layer.

### BRIEF DESCRIPTION OF THE DRAWINGS

FIG. 1 is a flow chart illustrating a method of forming a light emitting device, according to various embodiments of the present disclosure.

FIGS. 2-9 show cross-sectional views of a layered semiconductor-containing structure at various stages during the process of FIG. 1, according to various embodiments of the present disclosure.

FIG. 10 is a cross-sectional view of a light emitting device, according to various embodiments of the present disclosure.

### DETAILED DESCRIPTION

As stated above, the present disclosure is directed to an LED and a method of manufacturing the same, the various aspects of which are described below. Throughout the drawings, like elements are described by the same reference numeral. The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure.

Relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

As used herein, a “light emitting device” refers to any device that is configured to emit light and includes, but is not limited to, a light emitting diode (LED), a laser, such as a vertical-cavity surface-emitting laser (VCSEL), and any other electronic device that is configured to emit light upon application of a suitable electrical bias. A light emitting device may be a vertical structure (e.g., a vertical LED) in which the p-side and n-side contacts are located on opposite sides of the structure or a lateral structure in which the p-side and n-side contacts are located on the same side of the structure. As used herein, a “light emitting device assembly” refers to an assembly in which at least one light emitting device is structurally fixed with respect to a carrier structure, which can include, for example, a substrate, a matrix, or any other structure configured to provide stable mechanical support to the at least one light emitting device.

Devices can be fabricated on respective growth substrates. As used herein, a “growth substrate” refers to a substrate that is processed to form devices thereupon or therein. The devices can include light emitting devices. The devices can be formed as an array on the growth substrate.

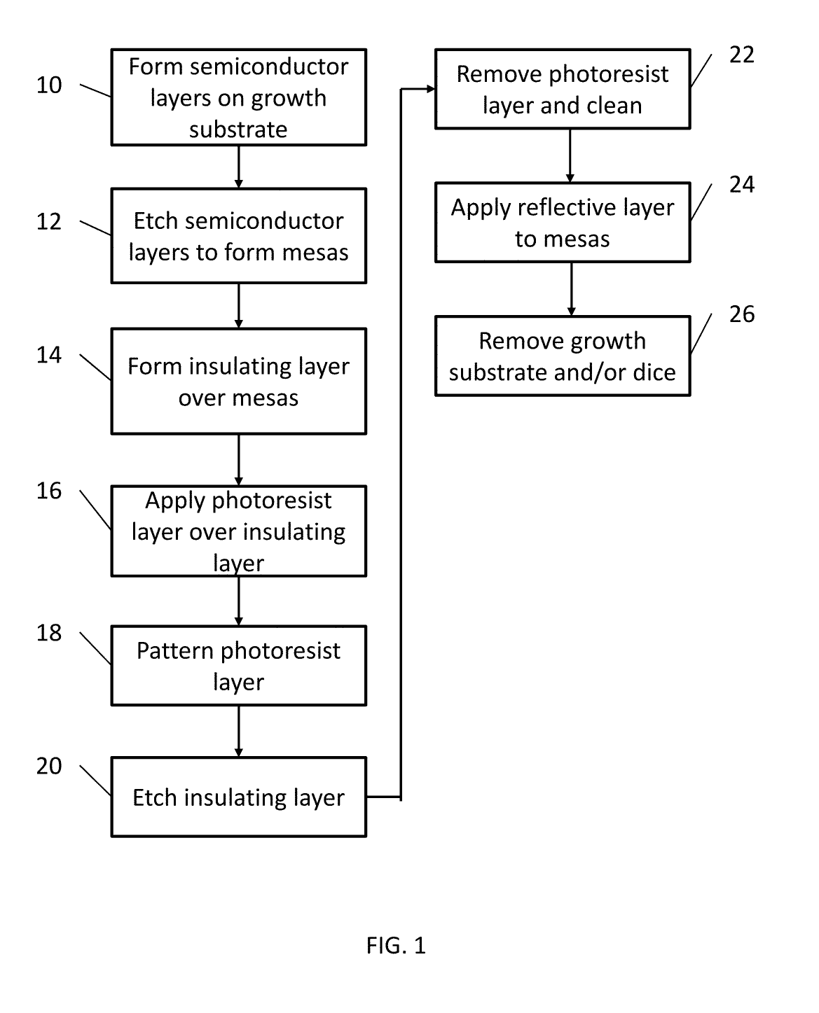

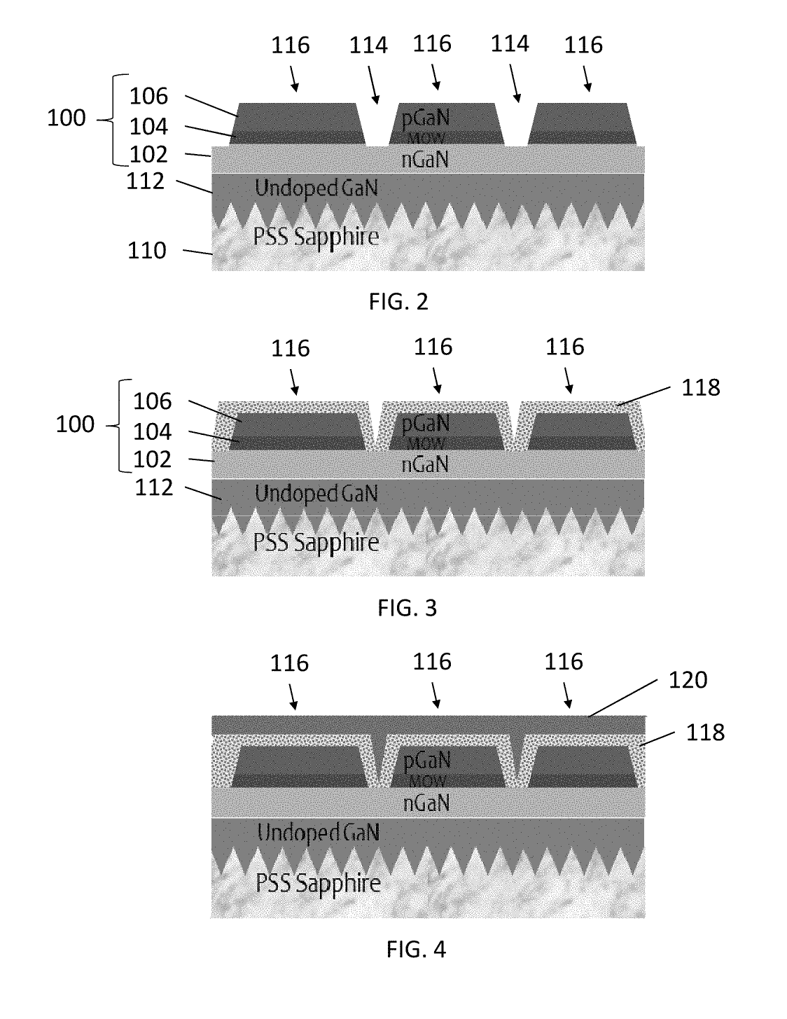

FIG. 1 is a flow chart illustrating a method of forming a light emitting device, according to various embodiments of the present disclosure. FIGS. 2-8 show cross-sectional views of a layered semiconductor-containing structure at various stages during the process of FIG. 1, according to various embodiments of the present disclosure.

Referring to FIGS. 1-8, step 10 of the method may include forming semiconductor layers 100 on a growth substrate 110. The growth substrate 110 may be a patterned (e.g., roughened or having a pattern of protrusions on its upper surface) sapphire substrate, a gallium nitride substrate, or a silicon substrate. The semiconductor layers 100 may be disposed on a patterned surface of the growth substrate 110.

The semiconductor layers 100 may include an active layer 104 disposed between a first semiconductor layer 102 and a second semiconductor layer 106. A buffer layer 112 may be disposed between the patterned surface of the growth substrate 110 and the semiconductor layers 100. The buffer layer 112 may be formed of an undoped or a doped semiconductor material, such as n-GaN or the like. Layers 102, 104, 106, 112 may be formed as single crystal epitaxial layers, or as polycrystalline semiconductor layers.

The first and second semiconductor layers 102, 106 may include a semiconductor material, such as GaN or the like. The first and second semiconductor layers 102, 106 may have different conductivity types. For example, the first semiconductor layer 102 may include n-type dopant, and the second semiconductor layer 106 may include a p-type dopant. However, in some embodiments, the first semiconductor layer 102 may include p-type dopant, and the second semiconductor layer 106 may include an n-type dopant. For convenience, the first and second semiconductor layers 102, 106 may be respectively referred to as an n-doped layer 102 and a p-doped layer 106.

The active layer 104 may be a light emitting layer having a multiple quantum well (MQW) structure. In some embodiments, the active layer 104 may include MQW structures formed of InGaN well layers and GaN barrier layers. However, other suitable light emitting semiconductor materials may be used.

In step 12, the semiconductor layers 100 may be etched to form a mesa structure, as shown in FIG. 2. In particular, grooves (e.g., trenches) 114 may be formed (e.g., etched) in the p-doped layer 106 and the active layer 104, such that mesas 116 are formed. The trenches 114 may be formed in a grid pattern or the like, such that the mesas 116 are generally rectangular when viewed from above. However, in some embodiments, the trenches 114 may be formed in other patterns, such that mesas 116 may be circular, ovoid, triangular, or the like. The mesas 116 may have angled side walls to facilitate light extraction. In other embodiments, the trenches may also extend completely through the semiconductor layers 100 (e.g., through the first semiconductor layer 102 in addition to the active and second semiconductor layers 104, 102).

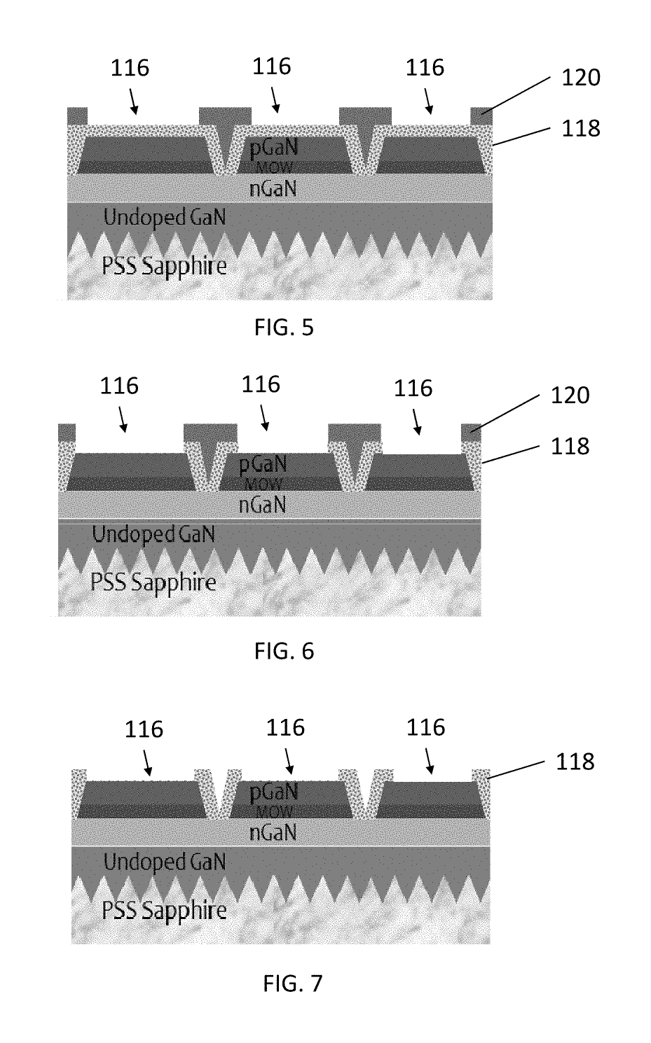

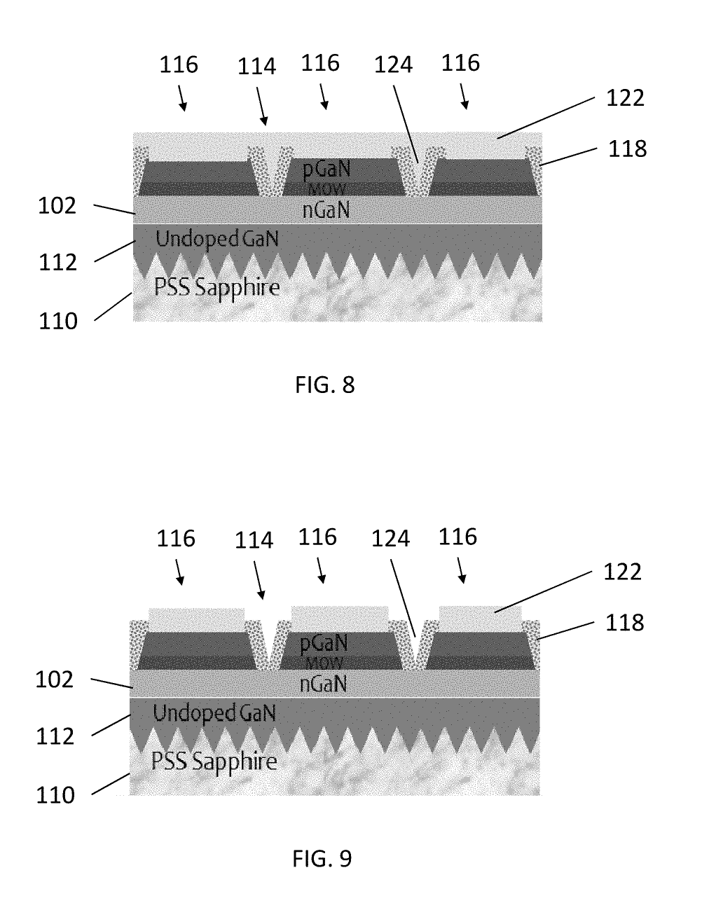

In step 14, an insulating layer 118 may be formed on the semiconductor layers 100, as shown in FIG. 3. The insulating layer 118 may be formed by any suitable method, such as a thin film deposition method, such as sputtering, CVD, or ALD. For example, the insulating layer 118 may be formed to cover upper surfaces of the mesas 116, sidewalls of the mesas 116 and/or exposed portions of the first semiconductor layer 102. The insulating layer 118 may include an electrically insulating inorganic material, such as silicon oxide (SiOₓ), silicon nitride (SiNₓ), Al₂O₃, ZnO, ZrO₂, TiO₂, Nb₂O₅, and Ta₂O₅. In step 16, a mask layer 120 may be formed on the insulating layer 118, as shown in FIG. 4. The mask layer 120 may be formed of a photoresist material, or the like. In step 18, the mask layer 120 may be patterned, as shown in FIG. 5. In particular, the mask layer 120 may be patterned by photolithography to expose portions of the insulating layer 118 disposed on upper surfaces of the mesas 116.

In step 20, the insulating layer 118 may be etched using the mask layer 120 as a mask, as shown in FIG. 6. In particular, upper surfaces of the mesas 116 may be exposed by the etching, while the sidewalls of the mesas 116 remain covered by the insulating layer 118. For example, the etching may expose from about 50% to about 95% of the upper surface of each mesa 116. In step 22, the mask layer 120 may be removed and the semiconductor structure may be cleaned, as shown in FIG. 7.

In step 24, a reflective contact layer 122 may be formed on the mesas 116, as shown in FIG. 8. The contact layer 122 may include a conductive, reflective material, such as Al, Ag, Ni, combinations thereof, or the like. In some embodiments, the contact layer 122 may include multiple layers of one or more different conductive and/or reflective materials. For example, the contact layer 122 may be formed by depositing a layer of indium tin oxide (ITO), Al, or Ag, and then depositing a layer of Ni, Ag, or a combination thereof, thereon.

The contact layer 122 may directly contact and or be electrically connected to the upper surfaces of the mesas 116 (i.e., to the second semiconductor layer 106). The insulating layer 118 may prevent the contact layer from electrically shorting the first semiconductor, active, and/or second semiconductor layers 102, 104, 106.

The contact layer 122 may include protrusions 124 that extend between the mesas 116, facing the insulating layer 118 covered sidewalls of the mesas 116 (e.g., may be disposed in the trenches 114). Accordingly, the contact layer 122 may reflect light emitted from the upper surfaces and sidewalls of the mesas 116. As such, the contact layer 122 may improve device light extraction efficiency.

In the alternative, step 24 may include forming the contact layer 122 only on the exposed upper surfaces of the mesas 116, as shown in FIG. 9. For example, the contact layer 122 may be formed and patterned using a laser lift-off technique.

The method may optionally include step 26, where the growth substrate 110 and/or buffer layer 112 may optionally be removed. In particular, the buffer layer 112 may facilitate the removal of the growth substrate 110 and/or prevent damage to the semiconductor layers 100. However, in other embodiments, the semiconductor structure may remain on the growth substrate 110.

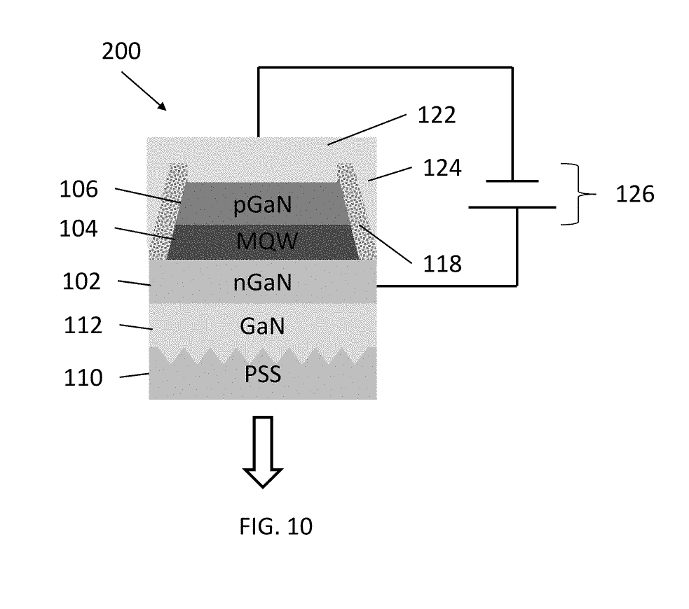

The semiconductor structure may also be diced into individual or groups of light emitting devices. For example, as shown in FIG. 10, the semiconductor structure may be diced into individual light emitting devices 200. In the alternative, the semiconductor structure may be diced into groups of light emitting devices 200 connected by the first semiconductor layer 102.

The light emitting device 200 may be a bottom emitting device and emit light in the direction of the arrow in FIG. 10. If present, the buffer layer 112 and/or growth substrate may have a patterned (e.g., roughened) surface corresponding to the patterned surface of the growth substrate 110, both of which may facilitate light extraction. The contact layer 122 may be a p-electrode which electrically contacts the second (i.e., p-type) semiconductor layer 106 and an n-type electrode (not shown) may be electrically connected to the buffer layer 112 of the first semiconductor layer 102, from above or below the substrate 110. The p-electrode and the n-electrode are connected to opposite polarity terminals of a power source 126, such as a battery or power grid connection.

The protrusions 124 of the contact layer 122 may face side surfaces of the active and second semiconductor layers 104, 106 and maybe configured to reflect laterally emitted light toward the buffer layer 112 and/or growth substrate 110, where the light may be extracted. Accordingly, the contact layer 122 may be configured to improve the light extraction efficiency of the light emitting device 200.

Although the foregoing refers to particular preferred embodiments, it will be understood that the invention is not so limited. It will occur to those of ordinary skill in the art that various modifications may be made to the disclosed embodiments and that such modifications are intended to be within the scope of the invention. Where an embodiment employing a particular structure and/or configuration is illustrated in the present disclosure, it is understood that the present invention may be practiced with any other compatible structures and/or configurations that are functionally equivalent provided that such substitutions are not explicitly forbidden or otherwise known to be impossible to one of ordinary skill in the art.

What is claimed is:

1. A method of forming a light emitting device, comprising:
forming a first semiconductor layer on a substrate;
forming an active layer on the first semiconductor layer, wherein the active layer is configured to emit light;
forming a second semiconductor layer on the active layer;
etching grooves into the second semiconductor layer and the active layer to form mesas;
forming an insulating layer on the mesas;
etching the insulating layer to expose upper surfaces of the mesas; and
forming a reflective contact layer on the mesas.

2. The method of claim 1, further comprising:
forming a photoresist layer on the insulating layer; and
patterning the photoresist layer,
wherein the etching the insulating layer comprises using the patterned photoresist layer as a mask.

3. The method of claim 1, wherein the reflective contact layer comprises protrusions disposed in the grooves on the etched insulating layer, and facing sidewalls of the mesas.

4. The method of claim 1, the forming a reflective contact layer comprises:
forming a first layer comprising ITO, Al, Ag, or any combination thereof, on the mesas; and
forming a second layer comprising Ni, Ag, or any combination thereof, on the first layer.

5. The method of claim 1, further comprising removing the patterned photoresist and cleaning the second semiconductor layer prior to forming the contact layer.

6. The method of claim 1, wherein the etching the insulating layer comprises exposing from about 50% to about 95% of the upper surface of each mesa.

7. The method of claim 1, further comprising a buffer layer disposed between the first semiconductor layer and the substrate.

8. The method of claim 1, wherein the etching grooves comprises etching the grooves through the second semiconductor layer and the active layer, without etching the first semiconductor layer.

9. The method of claim 1, wherein:
the reflective contact layer comprises ITO, Al, Ag, Ni, or any combination thereof;
the first semiconductor layer comprises n-type doped GaN;
the second semiconductor layer comprises p-type doped GaN; and
the insulating layer comprises silicon oxide (SiOₓ), silicon nitride (SiNₓ), Al₂O₃, ZnO, ZrO₂, TiO₂, Nb₂O₅, Ta₂O₅, or any combination thereof.

10. The method of claim 1, wherein the reflective contact layer electrically contacts the second semiconductor layer on upper surfaces of the mesas.

11. A light emitting device comprising:
a first semiconductor layer having a first conductivity type;
an active layer disposed on an upper surface of the first semiconductor layer and configured to emit light;
a second semiconductor layer disposed on an upper surface of the active layer and having a second conductivity type different from the first conductivity type;
an insulating layer covering sidewalls of the active layer and the second semiconductor layer; and
a reflective contact layer disposed on an upper surface of the second semiconductor layer and comprising protrusions disposed on the insulating layer facing the sidewalls of the active layer and the second semiconductor layer.

12. The device of claim 11, further comprising a buffer layer disposed on a lower surface of the first semiconductor layer.

13. The device of claim 12, wherein the buffer layer comprises a patterned lower surface.

14. The device of claim 12, wherein the protrusions of the contact layer are configured to reflect light emitted from the sidewalls of the active layer and the second semiconductor layer towards the buffer semiconductor layer.

15. The device of claim 11, wherein the active layer comprises a multi quantum well structure.

16. The device of claim 11, wherein the insulating layer comprises silicon oxide (SiOₓ), silicon nitride (SiNₓ), Al₂O₃, ZnO, ZrO₂, TiO₂, Nb₂O₅, Ta₂O₅, or any combination thereof and is configured to insulate the contact layer from the active layer and the first semiconductor layer.

17. The device of claim 11, wherein:
the first semiconductor layer comprises n-type doped GaN; and
the second semiconductor layer comprises p-type doped GaN.

18. The device of claim 11, wherein:
the contact layer directly contact the upper surface of the second semiconductor layer; and
the insulating layer electrically insulates the contact layer from the active layer, the first semiconductor layer, and the sidewalls of the second semiconductor layer.

19. The device of claim 11, wherein the contact layer comprises:
a first layer disposed directly on the upper surface of the second semiconductor layer and comprising ITO, Al, Ag, or any combination; and
a second layer comprising Ni, Ag, or any combination thereof, disposed on the first layer.

20. The device of claim 11, wherein:
the first semiconductor layer is continuous;
the second semiconductor layer and the active layer are patterned into mesas; and
the insulating layer is located on sidewalls of the mesas.
